(19) United States
(12) Patent Application Publication
(10) Pub. No.: US 2025/0027722 A1
(43) Pub. Date: Jan. 23, 2025

(54) THERMAL MANAGEMENT SYSTEM

(71) Applicant: VALEO SYSTEMES THERMIQUES, Le Mesnil-Saint-Denis (FR)

(72) Inventors: Julien Tissot, Le Mesnil-Saint-Denis Cedex (FR); Kamel Azzouz, Le Mesnil-Saint-Denis Cedex (FR); Jeremy Blandin, Le Mesnil-Saint-Denis Cedex (FR)

(73) Assignee: VALEO SYSTEMES THERMIQUES, Le Mesnil-Saint-Denis (FR)

(21) Appl. No.: 18/714,987

(22) PCT Filed: Nov. 17, 2022
(86) PCT No.: PCT/EP2022/082344

§ 371 Date: May 30, 2024

(30) Foreign Application Priority Data
Nov. 30, 2021 (FR) FR2112711

(51) Int. Cl. F28D 9/00; F28D 21/00; F28F 3/04; F28F 9/02

(52) U.S. Cl. CPC F28D 9/0056; F28F 3/044; F28F 9/0221; F28D 2021/0028; F28D 2021/008

(57) ABSTRACT

A heat exchanger is disclosed. The heat exchanger includes a stack of plates extending between an upper end plate and a lower end plate. The lower end plate includes four lateral walls extending in the direction of the stack. The stack of plates forms an alternation of first canals for the first fluid and of second canals for the second fluid. The heat exchanger includes a first inlet and at least two first outlets which are fluidically connected to the first canals. The upper end plate includes the first inlet. At least one of the lateral walls includes the at least two first outlets.

The invention relates to a heat exchanger of a system for the thermal management of electrical and/or electronic elements using a dielectric fluid. The invention is particularly intended to equip motor vehicles, in particular motor vehicles with electric or hybrid power units. The electrical and/or electronic elements are, for example, battery cells, or power electronics, intended for electric vehicles. As the market share represented by electric vehicles continues to grow, the problems of cooling/heating the battery packs with which they are equipped are taking on strategic importance. The electrical and/or electronic elements may also be, for example, electrical energy storage devices, computer servers or power electronics.

The objective is to design the best-performing, most efficient and economical electrical and/or electronic element thermal management system possible. Often, in order to meet the cooling/heating needs of electrical and/or electronic elements, use is made of heat exchangers that consist of a cold plate with a circulation of coolant, the plate being in contact with the elements that are to be cooled.

This kind of technique leads to non-uniform cooling, which has the effect of limiting the life and performance of the components. Furthermore, such devices have high thermal resistance because of the thicknesses of material present between the coolant and the elements that are to be cooled, and because of the thermal resistances, referred to as contact resistances, between the various components.

One proposed solution for addressing this set of problems is to immerse the electric and/or electronic elements in a dielectric heat-transfer fluid. This immersion can be achieved with a circulation fluid or under static conditions involving a phase change.

In both instances, the device comprises a thermal management system to maintain the temperature of the dielectric fluid. In the case of the second technique, which performs better because of the agitation of the fluid, the dielectric fluid is circulated through a heat exchanger using a pump.

The heat exchanger concerned is generally a plate-type exchanger which is both compact and good on performance, but which does generate significant pressure drops. Now, the circulation pump consumes electrical energy, the consumption being directly linked to the pressure drops generated by the heat exchanger.

The pressure drops generated by the plate exchanger can be divided into irregular pressure drops linked with specific irregularities, particularly at the distribution headers, and regular pressure drops in the canals formed by each pair of plates. Now, while the regular pressure drops are “useful” because they are linked to flow disturbances that are essential to the excellent thermal performance of the exchanger, the irregular pressure drops are nothing more than inconveniences associated with the geometry of the exchanger. In addition, the headers generate non-uniformities in the distribution of the fluid in the exchanger. These non-uniformities have an impact on the thermal performance of the exchanger.

The invention seeks to at least partially solve these problems by incorporating the exchanger directly into the battery pack. The exchanger is therefore immersed in the dielectric fluid. As a result, the dielectric fluid outlet header becomes superfluous, replaced by openings made in each of the canals of the exchanger, thereby making it possible to considerably reduce the pressure drops and their impact on the distribution.

More specifically, the invention relates to a heat exchanger, particularly for a motor vehicle thermal management system intended for the exchange of heat between a first fluid and a second fluid, comprising a stack of plates extending between an upper end plate and a lower end plate. The heat exchanger comprises four lateral walls extending in the direction of the stack, the stack of plates forming an alternation of first canals intended for the first fluid and of second canals intended for the second fluid. The heat exchanger further comprises a first inlet and at least two first outlets which are fluidically connected to the first canals, the upper end plate comprising the first inlet, at least one of the lateral walls comprising the at least two first outlets.

According to at least one of the aspects of the invention, the at least two first outlets open in the continuation of the first canals to which they are connected.

According to at least one of the aspects of the invention, the at least two first outlets are aligned with one another in the direction of the stack.

According to at least one of the aspects of the invention, the at least two first outlets are situated on the one same lateral wall.

According to at least one of the aspects of the invention, the lateral wall of the heat exchanger that comprises the at least two first outlets has an inset. Thus, a first plane containing the first outlets and a second plane incorporating the rest of the lateral wall are not coincident.

According to at least one of the aspects of the invention, the at least two first outlets are of elongate shape.

According to at least one of the aspects of the invention, the heat exchanger comprises as many first outlets as first canals.

According to at least one of the aspects of the invention, each first outlet of the first canals is formed by the edges of the two plates that form said canal.

According to at least one of the aspects of the invention, a first header fluidically connects the first inlet to the first canals.

According to at least one of the aspects of the invention, the first header extends between the upper end plate and the lower end plate of the heat exchanger.

According to at least one of the aspects of the invention, the heat exchanger comprises a second inlet and a second outlet which are fluidically connected to the second canals.

According to at least one of the aspects of the invention, the upper end plate or the lower end plate comprises the second inlet.

According to at least one of the aspects of the invention, the upper end plate or the lower end plate comprises the second outlet.

According to at least one of the aspects of the invention, a second header and a third header respectively fluidically connect the second inlet and the second outlet to the second canals.

According to at least one of the aspects of the invention, the second and third headers extend between the upper end plate and the lower end plate.

According to at least one of the aspects of the invention, the stack of plates is such that each of the plates of the stack of plates forms both part of a first canal and of a second canal.

According to at least one of the aspects of the invention, the heat exchanger is such that the upper end plate forms, with the immediately adjacent plate, a first canal or a second canal.

According to at least one of the aspects of the invention, the heat exchanger is such that the lower end plate forms, with the immediately adjacent plate, a first canal or a second canal.

According to at least one of the aspects of the invention, the two plates forming each of the second canals are joined together over the entirety of their periphery.

According to at least one of the aspects of the invention, the two plates forming each of the first canals are joined together over at least a fraction of their periphery.

According to at least one of the aspects of the invention, the plates forming the first and second canals are provided with a turned-up edge over at least part of their periphery.

According to at least one of the aspects of the invention, the plates are joined together by brazing.

According to at least one of the aspects of the invention, the first, second and third headers may be of circular, rectangular or triangular cross section.

According to at least one of the aspects of the invention, the first and second inlets and the second outlet may be of circular, rectangular or triangular shape.

According to at least one of the aspects of the invention, the first outlets are positioned at the opposite end of the heat exchanger from the first header.

According to at least one of the aspects of the invention, the first outlets are positioned at the same end of the heat exchanger as the first header.

According to at least one of the aspects of the invention, the first canals form an I-shaped flow path extending from a first lateral wall to a second lateral wall opposite the first.

According to at least one of the aspects of the invention, the first canals form a U-shaped flow path extending from a first lateral wall back to this same first lateral wall.

According to at least one of the aspects of the invention, the second canals form an I-shaped flow path extending from a first lateral wall to a second lateral wall opposite the first.

According to at least one of the aspects of the invention, the second canals form a U-shaped flow path extending from a first lateral wall back to this same first lateral wall.

According to at least one of the aspects of the invention, the plates are rectangular in shape.

The invention also relates to an assembly comprising a heat exchanger according to the invention and a circulation pump, characterized in that the first inlet of the heat exchanger is connected to the circulation pump, the circulation pump being placed facing and directly connected to the first inlet.

The invention also relates to a housing, said housing comprising a housing space configured to accommodate electrical and/or electronic components and to allow the circulation of the first fluid, said housing space having at least one wall.

According to at least one of the aspects of the invention, the housing is intended to allow a dielectric fluid to circulate.

According to at least one of the aspects of the invention, the housing comprises the heat exchanger or the assembly comprising the heat exchanger and the circulation pump.

According to at least one of the aspects of the invention, the heat exchanger or said assembly and/or the wall of the housing space is provided with a fixing system enabling mechanical connection between said heat exchanger or said assembly and said wall of the housing space.

According to at least one of the aspects of the invention, said fixing system could, for example, be fixed to the wall of the housing space by screws, staples, or a guideway.

According to at least one of the aspects of the invention, the housing comprises an outlet orifice fluidically connected to the first inlet of the heat exchanger, it being possible for said fluidic relationship to be direct or indirect. Said housing also comprises an inlet orifice fluidically connected to the first outlets of the heat exchanger.

According to at least one of the aspects of the invention, the housing comprises a double wall inside which the heat exchanger is housed. An internal wall of the housing then comprises an opening or a series of openings so that the first outlets are positioned facing and directly connected to this or these openings, the first outlets of the heat exchanger thus opening directly into the housing space.

According to at least one of the aspects of the invention, the housing space of the housing is at least partially filled with first fluid so that either the heat exchanger or an assembly comprising the heat exchanger and the circulation pump, is immersed in the first fluid.

The invention also relates to a thermal management system for the thermal management of electrical and/or electronic elements, comprising a first fluid circuit in which the first fluid circulates, said first fluid circuit comprising a housing, the housing space of said housing being at least partially filled with the first fluid and comprising an inlet and an outlet for the first fluid, the first fluid contained in the housing space circulating, directly or indirectly, from the outlet of the housing space toward the first inlet of the heat exchanger and supplying the first canals, the first outlets of the heat exchanger opening directly into the housing space, the second canals of the heat exchanger advantageously being connected to a second fluid circuit.

According to at least one of the aspects of the invention, the thermal management system is characterized in that the electrical and/or electronic elements may be, for example, electrical energy storage devices, battery cells, computer servers or power electronics.

According to at least one of the aspects of the invention, the heat exchanger is characterized in that the second fluid circuit, in which a second fluid circulates, is fluidically connected to the second canals of the heat exchanger. This second fluid circuit comprises at least a compressor, a second fluid/external-air exchanger and an expansion member.

According to one aspect of the invention, the heat exchanger is characterized in that the connections, on the one hand between the second inlet of the heat exchanger and the at least one wall of the housing space and, on the other hand, between the second outlet of the heat exchanger and the at least one wall of the housing space are fluidtight connections.

According to at least one of the aspects of the invention, the heat exchanger is characterized in that the sealing between the second fluid circuit and the at least one wall of the housing space is afforded by sealing gaskets.

According to at least one of the aspects of the invention, the heat exchanger is characterized in that the first fluid is intended to be in the liquid state at the operating pressure and temperature over at least part of the first fluid circuit.

According to at least one of the aspects of the invention, the heat exchanger is characterized in that the first fluid is a dielectric fluid.

According to at least one of the aspects of the invention, the heat exchanger is characterized in that the second fluid is intended to be in the two-phase liquid/vapor state at the operating pressure and temperature, this being over at least part of the second fluid circuit.

According to at least one of the aspects of the invention, the heat exchanger is characterized in that the second fluid is a refrigerant, for example R134a, R1234yf or R744.

The features, variants and different embodiments of the invention may be combined with one another, in various combinations, provided that they are not mutually incompatible or mutually exclusive. In particular, variants of the invention may be envisioned that comprise only a selection of features that are described in the present description in isolation from the other described features, if this selection of features is sufficient to provide a technical advantage.

Other features and advantages of the invention will become more clearly apparent from the following description and from a number of exemplary embodiments provided by way of non-limiting indication with reference to the appended schematic drawings, in which:

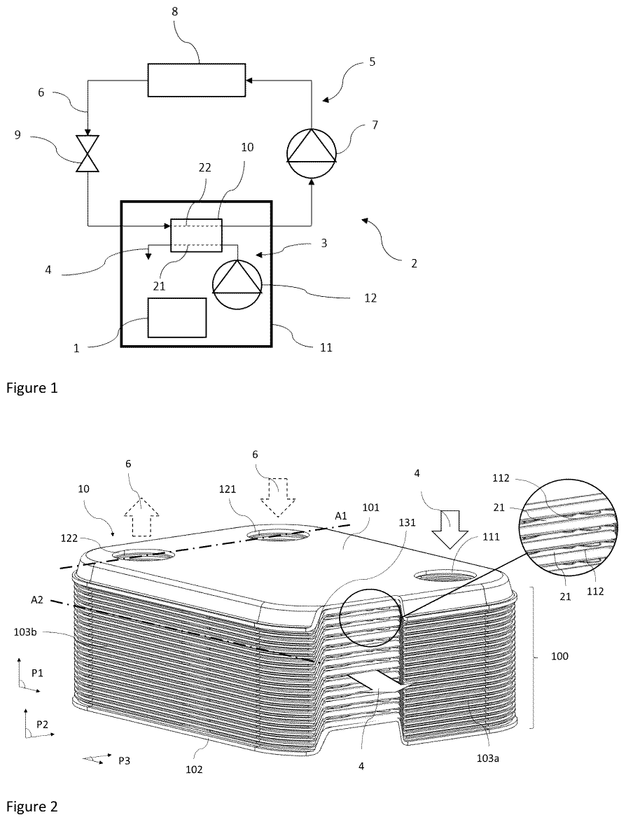

FIG. 1 is a schematic view of an installation comprising at least one heat exchanger according to the invention;

FIG. 2 is a perspective view of a heat exchanger forming part of the installation shown in FIG. 1;

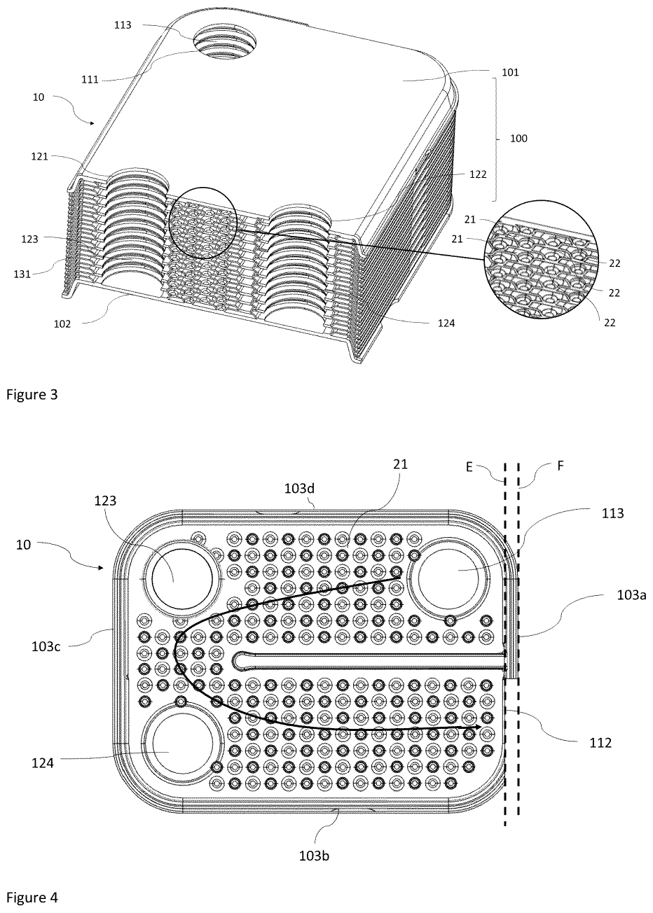

FIG. 3 is a perspective view of a section A1 on a plane P2, as indicated in FIG. 2, of the heat exchanger forming part of the installation shown in FIG. 1;

FIG. 4 is a view of a section A2 on a plane P3, as indicated in FIG. 2, of the heat exchanger forming part of the installation shown in FIG. 1;

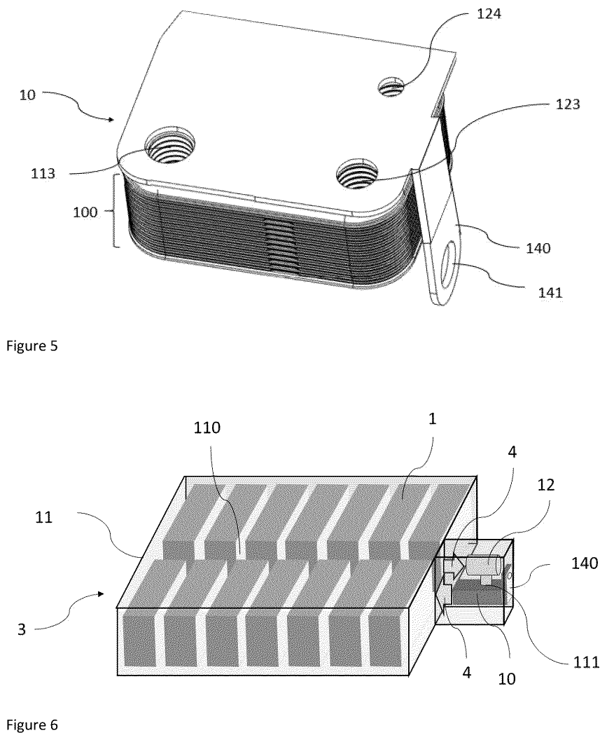

FIG. 5 is a perspective view of a heat exchanger forming part of the installation shown in FIG. 1, this exchanger being associated with a fixing system;

FIG. 6 is a perspective view of a housing incorporating a heat exchanger forming part of the invention.

In the various figures, unless indicated otherwise, elements that are identical bear the same reference numerals and offer the same technical features and modes of operation.

In FIG. 1, a motor vehicle is equipped with electrical and/or electronic elements 1 which need to be cooled or heated, for example in order to optimize the operation thereof. To this end, the motor vehicle is equipped with a thermal management system 2 which comprises a first fluid circuit 3 inside which a first fluid 4, notably a dielectric fluid or similar, circulates, and a second fluid circuit 5 inside which a second fluid 6, refrigerant of the carbon dioxide or similar type for example, circulates. The thermal management system 2 comprises at least one heat exchanger 10 according to the present invention. The thermal management system 2 is described below in order to provide a better understanding of the present invention, but the features of the thermal management system 2 described are in no way limiting for the heat exchanger 10 of the present invention. In other words, the thermal management system 2 is able to exhibit distinct structural features and/or modes of operation that differ from those described, without the heat exchanger 10 departing from the rules of the present invention.

The second fluid circuit 5 comprises a compressor 7 for compressing the second fluid 6, a second-fluid/external-air exchanger 8 for cooling the second fluid 6 at constant pressure, for example placed at the front of the motor vehicle, an expansion member 9 to permit expansion of the second fluid 6, and a first heat exchanger 10 which is designed to permit heat transfer between the second fluid 6 and the first fluid 4.

The first fluid circuit 3 comprises a circulation pump 12 for circulating the first fluid 4 within the first fluid circuit 3. The first fluid circuit 3 comprises the heat exchanger 10, which is also part of the second fluid circuit 5. The first fluid circuit 3 comprises the housing 11, so that the latter is at least partially filled with first fluid 4. The electrical and/or electronic elements 1 are immersed in the first fluid 4 contained in the housing 11. The heat exchanger 10 is able to cool the first fluid 4 in which the electrical and/or electronic elements 1 are immersed. The circulation pump 12, the heat exchanger 10 and the electrical and/or electronic elements 1 are immersed in the first fluid 4 and contained in the housing 11.

The heat exchanger 10 comprises at least one first canal 21 for the first fluid 4 and at least one second canal 22 for the second fluid 6, the first canal 21 and the second canal 22 being arranged to permit an exchange of heat between the first fluid 4 present inside the first canal 21 and the second fluid 6 present inside the second canal 22. Preferably, the first heat exchanger 10 has several first canals 21 and several second canals 22. A first canal 21 is interposed between two second canals 22, and a second canal 22 is interposed between two first canals 21. The heat exchanger 10 thus has an alternating arrangement of first canals 21 and second canals 22. Inside the first fluid circuit 3, the first fluid 4 is drawn up by the circulation pump 12 from the housing 11 toward the heat exchanger 10, then circulates in the first heat exchanger 10, following the first canals 21, to exchange heat energy with the second fluid 6 present inside the second canals 22, and then returns to the housing 11 before being drawn up once again by the circulation pump 12. Inside the second fluid circuit 5, the second fluid 6 circulates from the compressor 7 toward the second-fluid/external-air exchanger 8, then toward the expansion member 9. The second fluid 6 then circulates inside the heat exchanger 10, following the second canals 22 inside which the second fluid 6 exchanges heat energy with the first fluid 4 present inside the first canals 21, then returns to the compressor 7.

The first fluid 4 is intended to be in the liquid state at the operating pressure and temperature over at least part of the first fluid circuit 3. The second fluid 6 is intended to be in the two-phase liquid/vapor state at the operating pressure and temperature over at least part of the second fluid circuit 5. The second fluid is a refrigerant, for example R134a, R1234yf or R744.

A heat exchanger 10 according to the invention is depicted in perspective in FIG. 2. The heat exchanger 10, intended for the exchange of heat between a first fluid 4 and a second fluid 6, comprises a stack of rectangular plates 100 extending between an upper end plate 101 and a lower end plate 102. The heat exchanger 10 further comprises four lateral walls 103 extending in the direction of the stack.

The stack of plates 100 forms an alternating sequence of first canals 21 intended for the first fluid 4 and of second canals 22 intended for the second fluid 6. The heat exchanger 10 comprises a first inlet 111 and several first outlets 112 which are fluidically connected to the first canals 21. The upper end plate 101 comprises the first inlet 111, the lateral wall 103a comprising the first outlets 112.

In addition to the first inlet 111 and the second outlets 112, the heat exchanger 10 also comprises a second inlet 121 and a second outlet 122 which are fluidically connected to the second canals 22. In the configuration shown in FIG. 2, the upper end plate 101 comprises the second inlet 121 and the second outlet 122.

The first outlets 112 open in the continuation of the first canals 21 to which they are connected. The heat exchanger 10 comprises as many first outlets 112 as first canals 21, these outlets 112 being formed by the edges of the two plates 100 forming each of the first canals 21. These outlets are aligned with respect to one another in the direction of the stack 100 and are situated on the one same lateral wall 103a. The first outlets 112 are of elongate shape.

The plates 100 forming the first and second canals 21 and 22 are provided with a turned-up edge 131 over at least part of their periphery. The two plates 100 forming each of the second canals 22 are joined together over the entirety of their periphery. Because of the position of the first outlets 112, the two plates 100 forming each of the first canals 21 are joined together over only a fraction of their periphery. The plates 100 may, for example, be joined together by brazing.

FIG. 3 is a perspective view of a section A1 on a plane P2 of the heat exchanger 10 shown in FIG. 2. The heat exchanger 10 comprises three headers: the first header 113 fluidically connects the first inlet 111 to the first canals 21; the second header 123 fluidically connects the second inlet 121 to the second canals 22; the third header 124 fluidically connects the second outlet 122 to the second canals 22.

The first, second and third headers 113, 123 and 124 extend between the upper end plate 101 and the lower end plate 102. The first, second and third headers 113, 123 and 124, and the first and second inlets and the second outlet 111, 121 and 122 are of circular cross section. This shape is nonrestrictive and the headers 113, 123 and 124, and likewise the inlets and the outlet 111, 121 and 122 may, for example, be of rectangular or triangular cross section.

The stack of plates 100 is such that each of the plates 100 of the stack of plates 100 forms both part of a first canal 21 and part of a second canal 22. In addition, the upper end plate 101 and the lower end plate 102 each form, with the immediately adjacent plate 100, a first canal 21.

FIG. 4 is a view of a section A2 on a plane P3, of the heat exchanger 10 shown in FIG. 2. The plate 100 depicted corresponds to a first canal 21. According to the embodiment depicted, the first canals 21 form a U-shaped flow path extending from a first lateral wall 103a back to this same lateral wall 103a. According to another embodiment, the first canals 21 could form an I-shaped flow path extending from a first lateral wall 103a to a second lateral wall 103c. The same may be said of the second canals 22 which, according to this embodiment, form a U-shaped flow path but could equally form an I-shaped flow path.

In the case of flow path shown in FIG. 4, the first outlets 112 are positioned at the same end of the heat exchanger 10 as the first header 113.

That lateral wall 103a of the heat exchanger 10 that comprises the first outlets 112 has an inset. Thus, if a first plane E contains the first outlets and a second plane F incorporates the rest of the lateral wall, these two planes are not coincident.

FIG. 5 is a perspective view of the heat exchanger 10, this exchanger being associated with a fixing system 140. The fixing system 140, which comprises an orifice 141, allows mechanical connection between the heat exchanger and at least one of the walls of the housing 11. Said fixing system 140 could, for example, be fixed to the housing 11 by means of a screw or of a staple. The fixing system 140 could equally be provided with a guideway.

FIG. 6 shows a housing 11 incorporating an exchanger 10 according to the invention. The housing comprises a housing space 110 configured to accommodate electrical and/or electronic components 1 and to allow the first fluid 4 to circulate, said housing space 110 comprising at least one wall, preferably at least a bottom wall and pairwise opposite side walls. The housing 11 is intended to allow the circulation of the first fluid 4, it being possible for the first fluid 4 to be a dielectric fluid.

The housing 11 incorporates an assembly, this assembly comprising a heat exchanger 10 and a circulation pump 12. The assembly is characterized in that the heat exchanger 10 is connected to the circulation pump 12, the circulation pump 12 being positioned facing and connected to the first inlet 111. The heat exchanger 10 is mounted on one of the walls of the housing space 110. The heat exchanger 10 is provided with a fixing system 140 allowing it to be fixed to the wall of the housing space 110. Said fixing system 140 could, for example, be fixed to the wall of the housing space 110 by screws, staples or a guideway.

According to another embodiment, the fixing system 140 could be applied to the assembly comprising the heat exchanger 10 and the circulation pump 12. In that case, the fixing system 140 would enable said assembly to be fixed to the wall of the housing space 110.

Since the heat exchanger 10 is fixed to the wall of the housing space 110, the outlets 112 open into the housing space 110 and supply same with first fluid 4.

According to another embodiment, the housing space 110 may comprise a double wall inside which the heat exchanger 10 is housed. An internal wall of the housing space 110 would then comprise an opening or a series of openings so that the first outlets 112 would be positioned facing and directly connected to this or these openings, the first outlets 112 of the heat exchanger 10 thus opening directly into the housing space 110 of the housing 11.

The housing 11 is at least partially filled with first fluid 4 so that the assembly comprising the heat exchanger 10 and the circulation pump 12 is immersed in the first fluid 4.

The connections, which are not depicted in FIG. 6, on the one hand between the second inlet 121 and one of the walls of the housing space 110 and, on the other hand, between the second outlet 122 and one of the walls of the housing space 110 are fluidtight connections. The sealing between the second fluid circuit 5 and the wall of the housing space 110 of the housing 11 is afforded by sealing gaskets.

According to another embodiment, the circulation pump 12 could be sited outside the housing space 110. In that case, the connection between, on the one hand, the housing space 110 and the circulation pump 12 and, on the other hand, the circulation pump 12 and the first inlet 111 of the exchanger 10 are connections that are made through one of the walls of the housing space 110. Said connections are then rendered fluidtight by sealing gaskets.

The thermal management system 2 for the thermal management of electrical and/or electronic elements 1 comprises a first fluid circuit 3 in which the first fluid 4 circulates, said first fluid circuit 3 comprising a housing 11, the housing space 110 of said housing 11 being at least partially filled with the first fluid 4 and comprising an inlet and an outlet for the first fluid 4, the first fluid 4 contained in the housing space 110 circulating from the outlet of the housing space 110 through the circulation pump 12 toward the first inlet 111 of the heat exchanger 10 and supplying the first canals 21, the first outlets 112 of the heat exchanger 10 opening directly into the housing space 110, the second canals 22 of the heat exchanger 10 advantageously being connected to a second fluid circuit 5.

The electrical and/or electronic elements 1 may be, for example, electrical energy storage devices, battery cells, computer servers or power electronics.

1. A heat exchanger for a motor vehicle thermal management system for the exchange of heat between a first fluid and a second fluid, the heat exchanger comprising:
a stack of plates extending between an upper end plate and a lower end plate,
the lower end plate comprising four lateral walls extending in the direction of the stack,
wherein the stack of plates forms an alternation of first canals for the first fluid and of second canals for the second fluid;
a first inlet and at least two first outlets which are fluidically connected to the first canals,
the upper end plate comprising the first inlet, and
at least one of the lateral walls comprising the at least two first outlets.

2. The heat exchanger as claimed in claim 1,
wherein the at least two first outlets open in the continuation of the first canals to which they are connected.

3. The heat exchanger as claimed in claim 2,
wherein the at least two first outlets are aligned with one another in the direction of the stack.

4. The heat exchanger as claimed in claim 1,
characterized in that wherein a first header fluidically connects the first inlet to the first canals.

5. The heat exchanger as claimed in claim 1,
wherein the heat exchanger comprises a second inlet and a second outlet which are fluidically connected to the second canals.

6. The heat exchanger as claimed in claim 5,
wherein the upper end plate comprises the second inlet and the second outlet.

7. The heat exchanger as claimed in claim 6,
wherein a second header and a third header respectively fluidically connect the second inlet and the second outlet to the second canals.

8. An assembly comprising:
a heat exchanger as claimed in claim 1; and
a circulation pump,
wherein the first inlet of the heat exchanger is connected to the circulation pump,
wherein the circulation pump is placed facing and directly connected to the first inlet.

9. A housing comprising:
a housing space configured to accommodate electrical or electronic components and to allow the circulation of the first fluid,
wherein the housing space comprises at least one wall; and
a heat exchanger as claimed in claim 1,
wherein the heat exchanger or the wall of the housing space being is provided with a fixing system enabling mechanical connection between the heat exchanger and the wall of the housing space.

10. A thermal management system for the thermal management of electrical or electronic elements, the system comprising:
a first fluid circuit in which the first fluid circulates,
the first fluid circuit comprising a housing as claimed in claim 9,
wherein the housing space of the housing is at least partially filled with the first fluid and comprises an inlet and an outlet for the first fluid,
wherein the first fluid contained in the housing space circulates, directly or indirectly, from the outlet of the housing space toward the first inlet of the heat exchanger and supplies the first canals,
wherein the first outlets of the heat exchanger open directly into the housing space,
wherein the second canals of the heat exchanger are connected to a second fluid circuit.
